(19) United States
(12) Patent Application Publication
(10) Pub. No.: US 2025/0192068 A1
(43) Pub. Date: Jun. 12, 2025

(54) RECONFIGURABLE PACKAGE INTEGRATED ELECTRO MAGNETIC INTERFERENCE SHIELDING

(71) Applicants: Applied Materials, Inc., Santa Clara, CA (US); The Florida International University Board of Trustees, Miami, FL (US)

(72) Inventors: Ghaleb Saleh Ghaleb Al-Duhni, Miami, FL (US); Mudit Sunilkumar Khasgiwala, Milpitas, CA (US); Markondeyaraj Pulugurtha, Miami, FL (US); John Leonidas Volakis, Miami, FL (US); Kunal Ghosh, Bengaluru (IN); Meghna Maheshkumar Patel, Navsari (IN); Satheesh Bojja Venkatakrishnan, Miami, FL (US); Sachin Jayant Patil, Bengaluru (IN)

(73) Assignees: Applied Materials, Inc., Santa Clara, CA (US); The Florida International University Board of Trustees, Miami, FL (US)

(21) Appl. No.: 18/533,551

(22) Filed: Dec. 8, 2023

(51) Int. Cl. H01L 23/552; H01L 21/768; H01L 23/66

(52) U.S. Cl. CPC H01L 23/552; H01L 21/76816; H01L 23/66

(57) ABSTRACT

A tunable shielding system may include a substrate with a dielectric layer disposed on a surface of the substrate. The system may include a tunable metal patch including a metal plate attached to the substrate and encompassed in a magnetic layer, the tunable metal patch configured to be geometrically shifted. The system may include a direct current coil adjacent to the metal plate, and a current source. The system may include one or more processors and a computer readable medium including instructions that cause the system to perform operations to determine that an electromagnetic interference signal is incident on the system, the electromagnetic interference signal characterized by a frequency. The system may also determine a current amount associated with the frequency. The system may provide the current amount to the direct current coil such that a magnetic field is generated such that the tunable metal patch geometrically shifts.

### TECHNICAL FIELD

This disclosure generally relates to methods and systems for mitigating noise and other unwanted effects of electromagnetic radiation on an electronic device. More specifically, this disclosure describes techniques for designing and operating components on an electronic device to mitigate electromagnetic interference, enhance security, and achieve enhanced performance.

### BACKGROUND

Electronic devices, particularly those with antennas and/or receivers, may experience issues with electromagnetic (EM) radiation in the form of noise and interference, leading to performance and security issues. The configuration of an antenna and/or shielding of the antenna may be generally static. There is a need to enable the configuration to be modified quickly during normal operation of the electronic device in order to mitigate noise.

### BRIEF SUMMARY

A tunable shielding system may include a substrate. The system may include a dielectric layer disposed on a surface of the substrate. The system may include a tunable metal patch including a metal plate attached to the substrate and encompassed in a magnetic layer, the tunable metal patch configured to be geometrically shifted. The system may include a direct current coil adjacent to the metal plate. The system may also include a current source. The system may include one or more processors. The system may include a non-transitory computer readable medium may include instruction that, when executed by the one or more processors, cause the system to perform operations to determine, by the system, that an electromagnetic interference signal is incident on the system, the electromagnetic interference signal characterized by a frequency. The system may also determine, by the system, a current amount associated with the frequency. The system may provide, by the current source of the system, the current amount to the direct current coil such that a magnetic field is generated that causes the tunable metal patch to geometrically shift.

In some embodiments, the dielectric layer and the tunable metal patch may include at least one of an antenna and a metamaterial resonator ring. The tunable shielding system may be integrated in a semiconductor device and the electromagnetic interference signal may be generated from a source within the semiconductor device. The tunable metal patch may be configured to actuate in at least one of a vertical direction and a horizontal direction in response to the magnetic field. The current amount may be determined to shield the system from the electromagnetic interference signal. The magnetic layer may include a nickel iron alloy. The metal plate may be bonded to the substrate using at least one of an adhesive, solder, and a nickel-containing material. The direct current coils may be integrated in the tunable shielding system. The tunable metal patch may be configured as a spring and may include one or more cuts along opposite surfaces of the tunable metal patch. The spring may be formed from at least one of a metal and a polymer.

A method of forming a tunable metal patch may include depositing a first metal layer, depositing a second metal layer on the first metal layer, depositing a third metal layer, and depositing a bonding layer on the second metal layer. The method may include patterning the tunable metal patch such that the tunable metal patch is able to actuate in at least one direction in response to a magnetic field. The method may include providing a metal coil about the tunable metal patch, the metal coil configured to provide the magnetic field to the tunable metal patch.

In some embodiments, the first metal layer may include nickel ferrite. The second metal layer may include a copper containing material. The bonding layer may include a nickel containing material. The tunable metal patch may be attached to substrate may include at least one of zirconia, hafnium, aluminum, tungsten, and cobalt.

In some embodiments, the method may also include determining that an electromagnetic interference signal is incident on a system including the tunable metal patch, the electromagnetic interference signal characterized by a frequency. The method may also include determining a current amount associated with the frequency. The method may then include providing the current amount to the metal coil such that a magnetic field is generated that causes the tunable metal patch to geometrically shift.

A patch antenna may include an antenna dielectric. The patch antenna may include a cavity disposed in the antenna dielectric. The patch antenna may include a plurality of multiferroic structures within the cavity disposed in the antenna dielectric. The patch antenna may include a magnetic bias structure, configured to provide a magnetic field within the cavity of the antenna dielectric. The patch antenna may include a controller configured to provide a current to magnetic actuator structure such that the plurality of multiferroic structures alter their position within the cavity.

In some embodiments, the multiferroic structures may be platelets and include at least one of aluminum, zirconia, and hexaferrite. The multiferroic structures may be beads and include at least one of aluminum, zirconia, hafnium zirconium oxide, barium strontium titanate, strontium titanate, and hexaferrite. The cavity may include at least one of glass, liquid crystal polymer, parylene-coated polymer, and teflon.

### BRIEF DESCRIPTION OF THE DRAWINGS

FIGS. 1A and 1B illustrate a resonator with a tunable metal patch, according to certain embodiments.

FIGS. 2A and 2B illustrate a tunable metamaterial resonator element, according to certain embodiments.

FIG. 3 illustrates a tunable patch with shielding structures, according to certain embodiments.

FIGS. 4A-D illustrate a manufacturing process flow for forming of a tunable metal patch, according to certain embodiments.

FIG. 5 illustrates a flowchart of a method for manufacturing the tunable metal patch, according to certain embodiments.

FIG. 6 illustrates a reconfigurable antenna with dielectric tiles, according to certain embodiments.

FIG. 7 illustrates a reconfigurable antenna with a plurality of core/shell structures, according to certain embodiments.

FIGS. 8A-C illustrate a reconfigurable antenna with core/shell structures within a cavity, according to certain embodiments.

FIGS. 9A-D illustrate a manufacturing process flow for forming a reconfigurable antenna, according to certain embodiments.

FIG. 10 illustrates a flowchart of a method for forming a reconfigurable antenna, according to certain embodiments.

FIG. 11 illustrates an exemplary computer system, in which various embodiments may be implemented.

FIG. 12 illustrates a graph of isolation vs. frequency response due to a change in permittivity of a dielectric medium, according to certain embodiments.

FIG. 13 illustrates a graph isolation vs. frequency response due to a change in permittivity of a dielectric medium, according to certain embodiments.

### DETAILED DESCRIPTION

Electronic devices such as advanced packages face challenges in mitigating electromagnetic (EM) effects due to noise, EM interference (EMI), and other issues. EMI can disrupt components included in the electronic device, whether the EMI comes from other components included in the same device or from some other external source. EMI may also be electromagnetic noise (sometimes referred to as “noise”) is an unintended emission of EM radiation due to the operation of componentry on an electronic device, such as thermal noise. Thermal noise is caused by the excitation of charge carriers within components of an electronic device. This noise may cause components of an electronic device to emit EM radiation within a certain frequency band, causing similar effects on other components of the electronic device as EMI.

A number of system level and package level approaches have been adopted to shield components from both internal and external EMI. However, with increasing miniaturization, the need for miniaturized shields offering equal or better isolation also increases. Metal cans and metallized over-molds may be methods of EMI suppression for an advanced package. Such approaches lead to thick shield structures and may only shield one package from others. Individual dies and/or electronic devices included in the advanced package may still interfere with one another, however. Thus, it is critical to shield the individual dies and/or electronic devices included in the advanced package from one another in a single package.

Additionally, different components of the advanced package may emit and/or be sensitive to different noise patterns (e.g., frequencies, power, etc.). The noise patterns may also vary depending on a state of the advanced package. For example, during operation, a particular component of the advanced package may emit different noise patterns based on its operating state. A static shielding structure may therefore be effective against one noise pattern but lose effectiveness as the noise pattern shifts. Therefore, there is a need for a configurable shielding structure that can be tuned to shield a component of an advanced package during operation of the advanced package.

Many shielding structures utilize inductor-capacitor resonators (LC resonators) to shield components such as a patch antenna. The shielding effectiveness of such a device may be dependent on the physical properties of the LC resonator. Therefore, shifting the physical properties (e.g., material properties) of the LC resonator may shift the shielding properties of the resonator. One technique of providing reconfigurable shielding may therefore include a patch antenna with a changeable geometry. Shielding can also be affected by changing the antenna geometry. As an example, a patch antenna may include a tunable metal patch. The tunable metal patch may be coated in a magnetic substance, and configured to extend in one or more directions in response to an electrical current, a magnetic field, or other stimulus. The tunable metal patch may be perceived as a LC resonator. When a component experiences EMI, a magnetic field may be provided at or near the tunable metal patch that causes the tunable metal patch to extend (or retract). In other words, the physical properties of the patch antenna may be tuned in order to alter the shielding effectiveness (or other properties) the patch antenna and/or shielding structure.

Another solution may be to alter other properties of the patch antenna itself by the inclusion of multiferroic structures. A multiferroic material is a material that exhibit multiple ferroic properties (e.g., ferromagnetism, ferroelectricity, and ferroelasticity) in the same phase. By applying a magnetic field to the multiferroic structures, the properties of the multiferroic structures may be altered, and the shielding (or other properties) of the patch antenna and/or related structures may also be altered. For example, a patch antenna may be manufactured to include a cavity a dielectric material of the patch antenna. A plurality of multiferroic structures may be disposed in the cavity. A metal layer (e.g., a magnetic bias structure), may then be disposed on the dielectric material. A current may then be applied to the metal layer. The resulting magnetic field may cause the multiferroic structures to shift within the cavity. Because the multiferroic structures may include their own characteristics (e.g., permittivity, magnetic field, etc.) shifting within the cavity of the dielectric may cause the properties of the dielectric to shift. Thus, by controlling the placement of the multiferroic structures within the cavity, the properties of the patch antenna may be tuned to shield the antenna from EMI, adjust the transmissive/receptive properties of the antenna, or tune the patch antenna on other such ways.

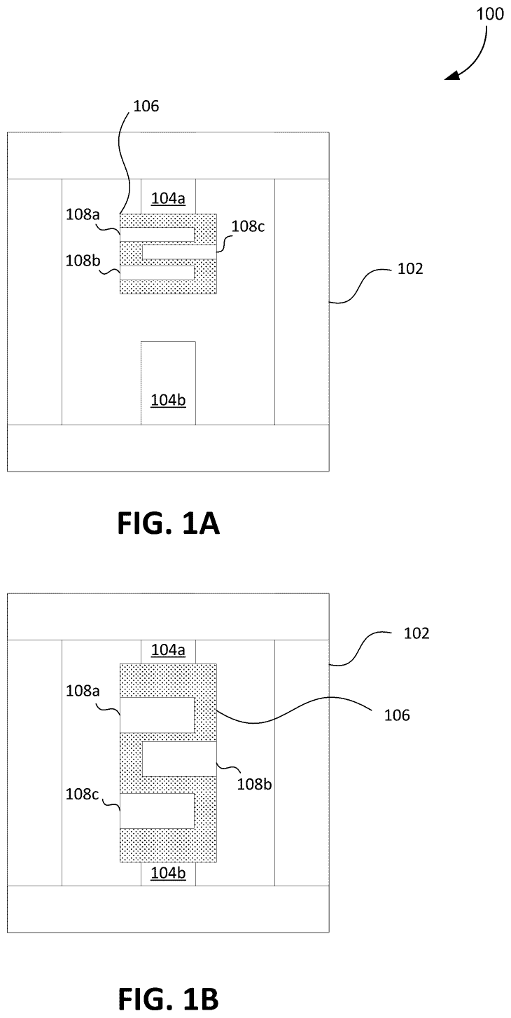

FIGS. 1A and 1B illustrate a resonator 100 with a tunable metal patch 106, according to certain embodiments. The tunable metal patch 106 may form a reconfigurable element such as a metamaterial ring resonator. The resonator 100 may be included in a semiconductor device, such as an advanced package. The resonator 100 may additionally or alternatively be included as part of a patch antenna. The resonator 100 may shield the patch antenna (or other device) from EMI or other interference. The resonator 100 may include a main body 102 and pillars 104a-b. The tunable metal patch 106 may connected to one or both of the pillars 104a-b that act as extension elements to connect to the tunable patch 106. The main body 102 may be manufactured using materials such as copper, nickel-coated copper, and/or other types of anti-tarnish copper. The main body 102 and/or the pillars 104a-b may be coated in a dielectric materials such as zirconia and/or other suitable materials. Besides acting as a dielectric, the coating may also reduce friction between the pillars 104a-b and the tunable metal patch 106, such that the tunable metal patch may slide over the pillars 104a-b repeatedly while reducing wear of the individual components.

The tunable metal patch 106 may be manufactured from a metal such as copper, iron, cobalt, and/or other suitable materials. In some embodiment, the tunable metal patch may include a magnetic layer, such as a nickel iron alloy. The tunable metal patch 106 may also be coated in a dielectric. The dielectric coating may alter the capacitive or other electrical properties of the tunable metal patch 106, as well as reduce friction between the tunable metal patch 106 and the pillars 104a-b. The tunable metal patch 106 may include one or more features 108a-c. The features 108a-c may be gaps in one or more sides of the tunable metal patch 106. The features 108a-c may allow the tunable metal patch 106 to expand and contract in response to some stimuli. For example, a metal coil may be placed near the resonator 100 (e.g., included in an advanced package or other semiconductor device with the resonator 100). Additionally or alternatively, a via may be drilled to form a single or multiturn coil for creating DC magnetic fields. The coils may then be filled with metal pastes and copper patterning, thus forming the metal coil around the tunable metal patch 106. When a current (e.g., a direct current (DC)) is provided to the metal coil, a magnetic field may be generated. The tunable metal patch 106 may then extend in a direction in response to the magnetic field.

In FIG. 1A, the tunable metal patch 106 may be in a first position. The resonator 100 may therefore have a first set of electrical properties (e.g., capacitive) based at least in part on the geometric configuration of the tunable metal patch. As shown in FIG. 1A, a gap map be present between the pillars 104a-b. The gap may be determined by a desired capacitive property of the resonator 100 at the first position.

In FIG. 1B, the tunable metal patch 106 may extend from the pillar 104a to the pillar 104b. The tunable metal patch 106 may extend due to a DC current being applied to a metal coil. The tunable patch may also extend by containing the tiles in a cavity and reconfiguring with a magnetic bias. The cavity may be composed of glass, liquid crystal polymer, parylene-coated polymers or Teflon, and may have hydrophobic coatings to prevent stiction. This may permit smooth movement of the metal tiles. For example, the resonator 100 may be a part of a shielding structure included in an advanced package or other semiconductor device. EMI may be incident on the semiconductor device (or a component thereof). In some embodiments, the EMI may originate from outside the semiconductor device. In other embodiments, the EMI may originate from an aggressor included in the same semiconductor device as the resonator 100. One or more components of the semiconductor device may detect the EMI and properties such as a frequency of the EMI. The semiconductor device may then determine a current amount to provide to the metal coil based on the frequency of the EMI (e.g., by accessing a lookup table or other such datastore). The current amount may cause a magnetic field to be generated that shifts the geometry of the tunable metal patch, shielding the semiconductor device from the EMI. In other words, the resonator 100 may be tuned to shield the semiconductor device based on the frequency of EMI incident on the system.

As shown, the tunable metal patch 106 may extend such that there is no gap between the pillars 104a-b. In some embodiments, the tunable metal patch 106 may extend only some way towards the pillar 106b, such that a gap is still present. In some embodiments, there may be a tunable metal patch attached to each of the pillars 104a-b such that there is a gap between the two tunable metal patches. The magnetic field generated via the DC current flowing through the metal coil may then cause one or both of the tunable metal patches to move, changing the electrical properties of the resonator 100.

For example, the integration of variable capacitances may provide dynamic control over capacitance by altering the plate geometry or the dielectric medium of the geometry. Modification of the permittivity of the dielectric medium at the gap is one such mechanism. These capacitance changes may influence resonance and electromagnetic interactions between components in applications such EMI management/mitigation. Analysis validation shows that changes in capacitance of such structures impact the distributed inductor-capacitor (metamaterial) structure's transmission bands by altering their coupling frequency and strength. The coupling loss may therefore increase, and the isolation improve.

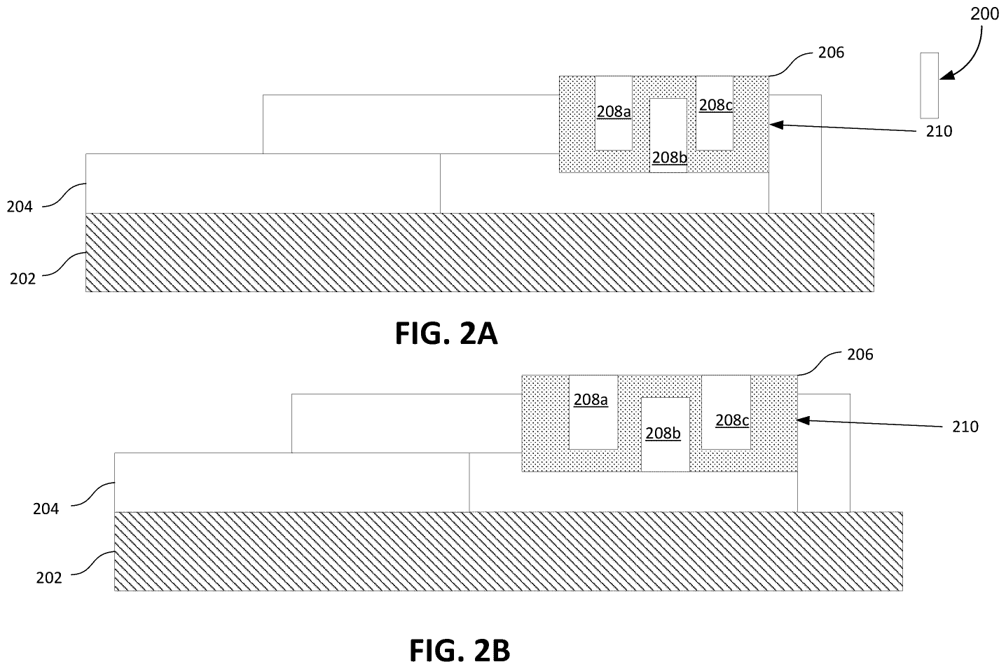

FIGS. 2A and 2B illustrate a tunable patch element 200 with a tunable metal patch 206, according to certain embodiments. The tunable patch element 200 may be included in a semiconductor device or other electronic device. With the inclusion of the tunable metal patch 206, the tunable patch element 200 may be reconfigurable to alter one or more electrical properties of the tunable patch element 200, leading to better performance. The tunable patch element 200 may include an antenna dielectric 202, a metal layer 204, and the tunable metal patch. The antenna dielectric 202 may be manufactured from low-loss organic laminates of epoxy with glass cloth or fillers, fluoropolymer laminates, ceramics such as alumina, glass or glass-ceramics, and other suitable materials. The metal layer 204 may include copper, tungsten, cobalt, zirconium, hafnium, aluminum, and/or any other suitable metals. In some embodiments, some or all of the metal layer 204 may be coated in a dielectric layer. The dielectric layer may alter the electrical properties of the tunable patch element 200 and/or reduce friction between the tunable metal patch 206 and the metal layer 204.

The tunable metal patch 206 may be similar to the tunable metal patch 106 in FIGS. 1A and 1B. As such, the tunable metal patch 206 may be manufactured from a metal such as copper, iron, cobalt, and/or other suitable materials such as allots thereof. In some embodiment, the tunable metal patch may include a meta material The tunable metal patch 206 may also be coated in a dielectric. The dielectric coating may alter the capacitive or other electrical properties of the tunable metal patch 106, as well as reduce friction between the tunable metal patch 206 and the metal layer 204. The tunable metal patch 206 may also include features 208a-c. The features 208a-c may allow a geometry of the tunable metal patch 206 to be altered. For example, the features 208a-c may allow the tunable metal patch 206 to act as a spring. The features 208a-c may be cuts or gaps in one or more sides of the tunable metal patch 206.

The tunable metal patch 206 may be microassembled (e.g., via a MEMS process) and later attached to the dielectric layer and/or the tunable metal patch 206 may be manufactured via a deposition/etching process. In some embodiments, the tunable metal patch 206 may include an anchor point 210 at which the tunable metal patch 206 is attached to the metal layer 204. The tunable metal patch 206 may attached via adhesive, welding, mechanical connection, or any other suitable method. The features 208a-c may be manufactured via mechanical cutting, laser cutting, etching, or any other suitable process. The tunable patch 200 may also be disposed in a cavity. This may be achieved by introducing the patches inside a cavity and sealing the cavity. The patches may move inside via a magnetic bias. The sealed cavity with pre-introduced tiles may be refabricated and microassembled to the appropriate feedpoints of control circuitry.

Similar to the resonator 100 in FIGS. 1A and 1B, a metal coil may be disposed near the tunable patch element 200. A DC current may be applied to the metal coil, such that a magnetic field is generated. In response to the magnetic field, the tunable metal patch 206 may extend along the metal layer 204.

In FIG. 2A, the tunable patch element 200 may be included in an electronic device (e.g., a semiconductor device, advanced package, etc.). The tunable metal patch 206 may be in a first position. The first position may allow the tunable patch element 200 to operate according to a first set of parameters (e.g., a certain direction, frequency, power, etc.). One or more components of the electronic device may determine that the tunable patch element 200 should be altered to operate according to a second set of parameters to reduce EMI, improve performance, etc. The one or more components may then determine a current amount needed to generate a certain magnetic field (e.g., in a lookup table). The one or more components may then provide a DC current in the current amount to a metal coil. The resulting magnetic field may then cause the tunable metal patch 206 to extend, as shown in FIG. 2B, and the tunable patch element 200 may operate according to the second set of parameters.

In some embodiments, the metal patches are contained in a cavity. The patches may be broken into elements with narrow separations and selected elements can be displaced. The antenna's performance may not be affected by breaking them into isolated elements or tiles. These tiles may be reconfigured to shift the transmission bands of the antenna and prevent any jamming by a hacker. This is particularly beneficial in altering the transmission These patches can shift with magnetic bias and can tune the patch antenna. By shifting the band of the patch, the patch is essentially shielding from one band while conveniently transmitting in the other band.

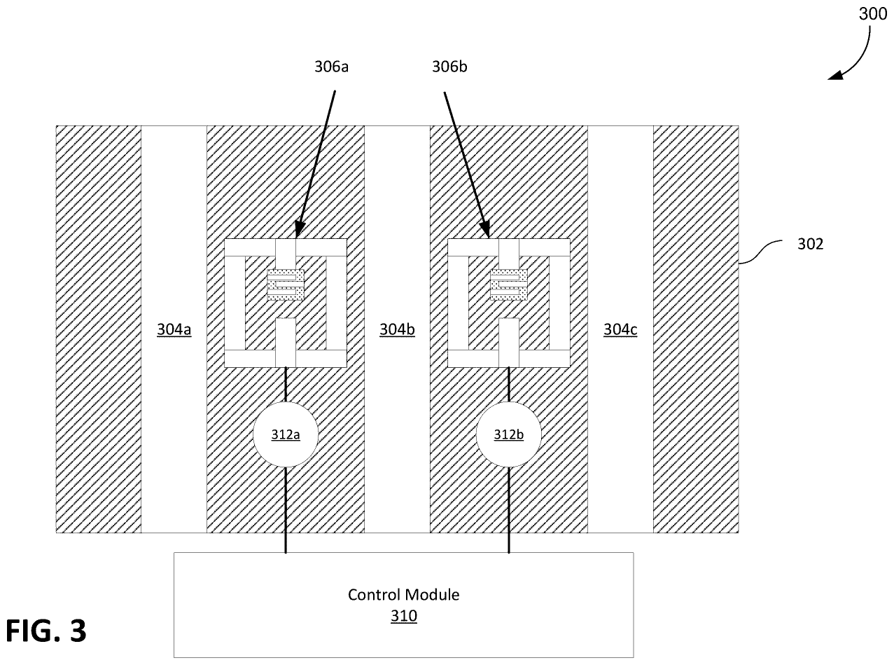

FIG. 3 illustrates a tunable patch 300 with shielding structures 306a-b, according to certain embodiments. The tunable patch 300 may be similar to the tunable patch element 200 in FIGS. 2A and 2B, and/or may form a standard patch antenna (e.g., not reconfigurable) and be included in semiconductor device. The shielding structures 306a-b may include a resonator, similar to the resonator 100 in FIGS. 1A and 1B, and include similar components and functionalities. The tunable patch 300 may include an antenna dielectric 302 and metal layers 304a-c. Each of the metal layers 304a-c may operate at similar frequencies as the other metal layers 304a-c, or may operate at different frequencies. The shielding structures 306a-b may operate to shield each of the metal layers 304a-c from sources within the semiconductor device and/or from outside sources of EMI. Thus, the shielding structures 306a-b may be tunable shielding structures. The shielding devices 306a-c may be connected to a control module 310. The control module 310 may include one or more processors, a non-transitory memory containing instructions, and one or more components to detect EMI and properties thereof. The control module 310 may also include a current source, for providing a DC current to metal coils 312a-b.

During operation, the control module 310 may detect EMI affecting one or more of the metal layers 304a-c. In response, the control module may determine a current amount to provide to one or both of the metal coils 312a-b (e.g., by accessing a lookup table or other data store) such that the shielding structures 306a-b reduce the EMI incident on the metal layers 304a-c. The control module 310 may then provide a DC current in the current amount to the metal coils 312a-b. A resulting magnetic field(s) from the metal coils 312a-b may then cause the shielding structures 306a-b to geometrically shift. For example, the shielding structures 306a-b may include tunable metal patches. The magnetic field(s) may then cause the tunable metal patches to extend in a direction, altering the electrical properties of the shielding structures 306a-b.

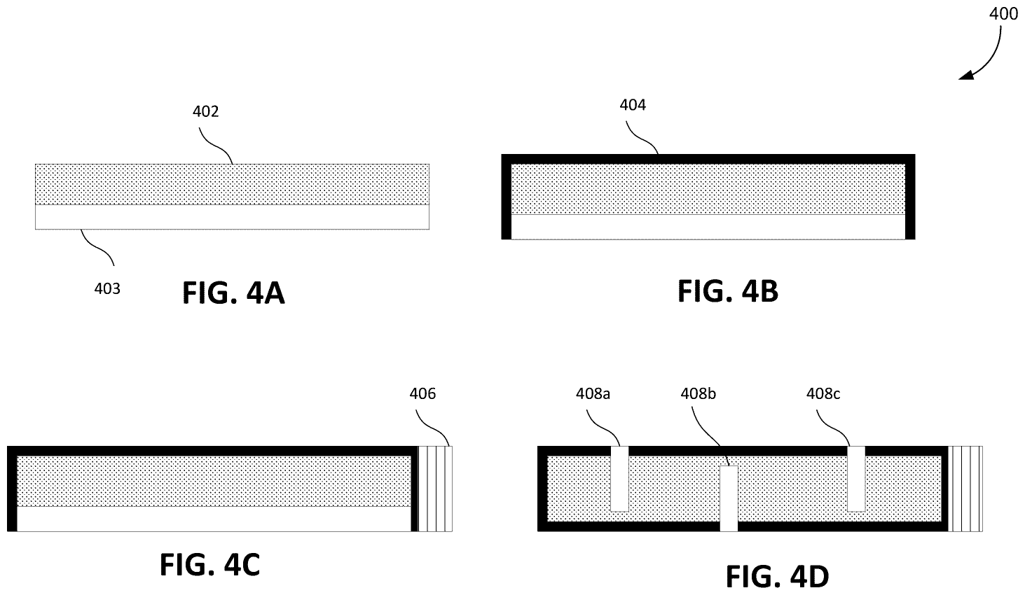

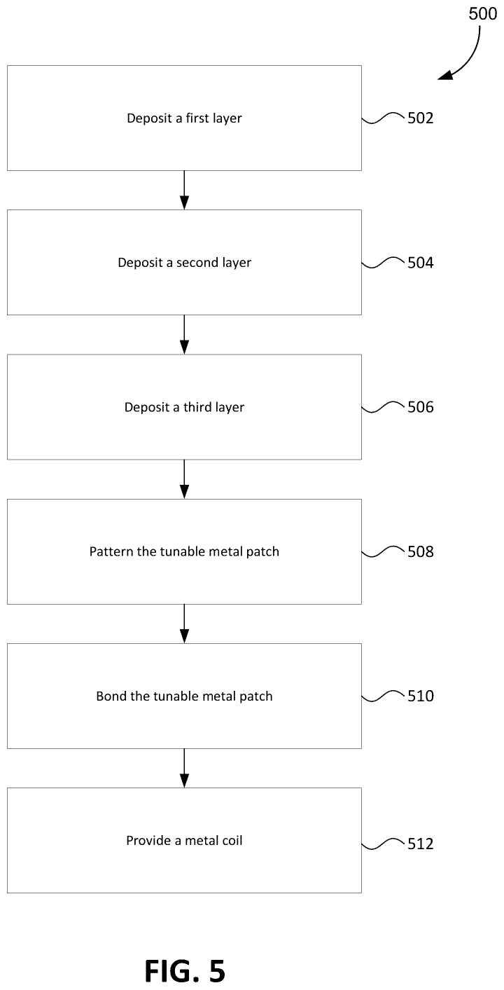

FIGS. 4A-D illustrate a manufacturing process flow for forming of a tunable metal patch 400 according to certain embodiments. FIG. 5 illustrates a flowchart of a method 500 for manufacturing the tunable metal patch 400, according to certain embodiments. The steps of the method 500 may be performed in a different order than is described and shown, and some steps may be combined with other. In some embodiments, some steps of the method 500 may be skipped altogether. FIGS. 4A-D will be described in conjunction with FIG. 5. The tunable metal patch 400 may be similar to the tunable metal patches 106 and 206 in FIGS. 1A-B and FIGS. 2A-B, respectively. Thus, the tunable metal patch 400 may be included in a resonator, patch antenna, or any other suitable device.

At step 502, the method 500 may include depositing a first metal layer 401. The first metal layer 401 may include a nickel layer. The first metal layer 401 may act as a bonding surface to which the tunable metal patch 400 may be later connected to an electronic device. The first metal layer 401 may be formed via a chemical deposition process (CDP), vapor deposition process (VDP), or other such process. The first metal layer 401 may be formed at least in part using photoresist patterning.

At step 504, the method 500 may include depositing a second metal layer 402 on the first metal layer 401. The second metal layer 402 may include copper, tungsten, cobalt, or any other suitable metal. The second metal layer 402 may be a metal patch that provides structure to the tunable metal patch 400.

At step 506, the method 500 may include depositing a third metal layer 404 on the second metal layer 402. The third metal layer 404 may be a magnetic configured to create actuation forces such that the geometry of the tunable metal patch may shift due to a magnetic field (e.g., the tunable metal patches 106 and 206). The third metal layer 404 may be deposited via a CDP or VDP, or may be plated using a photoresist mold or other such process.

At step 508, the method 500 may include depositing a bonding layer 406 on the third metal layer 404. The bonding layer 404 may only be deposited at specific points of the tunable metal patch 400 (e.g., the anchor point 210 in FIGS. 2A-B). The bonding layer 406 may therefore be utilized to attached the tunable metal patch 400 on a structure directly, such as the main body 102. In other embodiments, the bonding layer 406 may attach the tunable metal patch to intermediate structures, such as a MEMS-manufactured spring.

At step 510, the method 500 may include patterning the tunable metal patch 400 such that the tunable metal patch is able to actuate in at least one direction in response to a magnetic field. Patterning the tunable metal patch 400 may include cutting or ablating some or all of the layers of the tunable metal patch 400 to produce the features 408a-c. The features 408a-c may be disposed on opposite sides of the tunable metal patch 400.

At step 512, the method 500 may include providing a metal coil about the tunable metal patch. The metal coil may create a magnetic bias structure. To provide the metal coil, a via may be drilled in the tunable metal patch 400 and/or a structure to which the tunable metal structure will be attached. The via may form a single or multiturn coil for creating DC magnetic fields. The coils may then be filled with metal pastes and/or copper patterning, thus forming the metal coil.

In some embodiments, the tunable metal patch 400 may be attached to a substrate (e.g., the main body 102, the metal layer 204, etc.). The substrate may include zirconia, hafnia, alumina, tungsten, and/or cobalt. The method 500 may also include determining that an EMI signal is incident on the system. The EMI signal may be characterized by a frequency. The EMI may be emitted by a component of the electronic device including the tunable metal patch 400 and/or may be from a separate device. The method 500 may also determining a current amount associated with the frequency (e.g., by accessing a lookup table). The method 500 may then include providing the current amount to the metal coil such that a magnetic field is generated that causes the tunable metal patch 400 to geometrically shift. For example, the tunable metal patch 400 may extend vertically and/or horizontally.

The patches may be broken into elements with narrow separations and selected elements can be displaced. The antenna's performance may not be affected by breaking them into isolated elements or tiles. These tiles may now be reconfigured to shift the transmission bands of the antenna and prevent any jamming by a hacker. This may be particularly beneficial in altering the transmission bands and shielding bands for the antennas. For example, a displacement of 10 small tiles of the patch to the left by 100 microns may result in a shift in the antenna's operational frequency, transitioning from 9.54 to 10.15 GHz. This alteration in performance and control parameters underscores the sensitivity of the patch antenna to structural adjustments. If the antenna is broken to fewer tiles, manipulation may be easier to achieve. In contrast to the performance impact of moving the left-edge elements to the left, relocating 10 right-edge elements to the right may result in a shift in the operational frequency to 10.3 GHz from the initial 9.545 GHz. Notably, in this configuration, the gain may experience a 15% increase as opposed to a decrease observed in the leftward shift. The asymmetric nature of the response may be affected by changing the feed-location of the antenna.

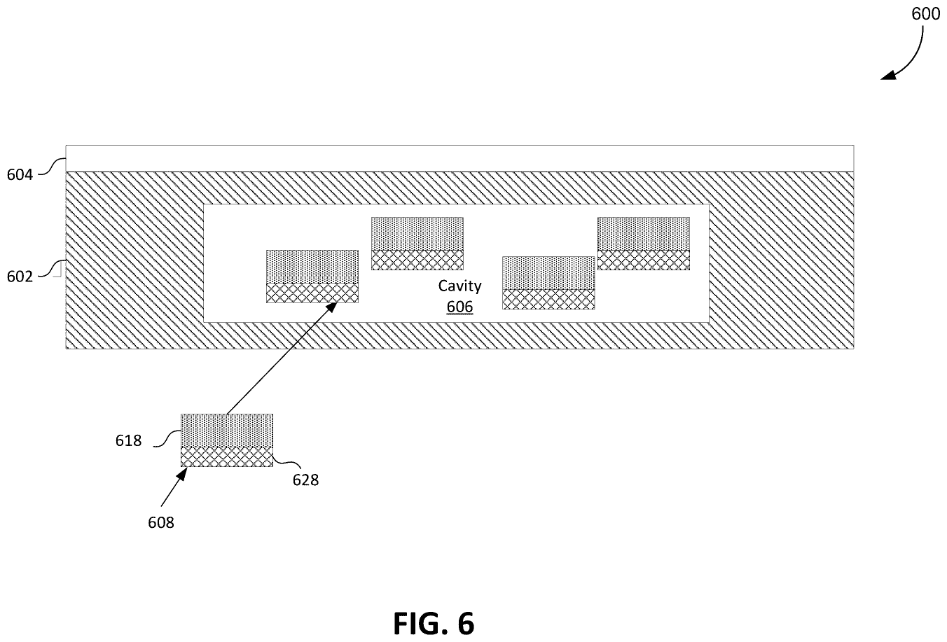

FIG. 6 illustrates a reconfigurable antenna 600 with dielectric tiles 608, according to certain embodiments. The reconfigurable antenna 600 may be included in an electronic device, such as an advanced package, or some other device. Similar to the tunable patch element 200 in FIGS. 2A-B, the reconfigurable antenna 600 may be tuned in order to reduce the effects of EMI (both as a victim and an aggressor), improve performance, change transmission/reception frequencies, or be otherwise altered. Instead of altering the geometry of a metal patch, however, the reconfigurable antenna 600 may be altered by reconfiguring the electrical properties within a dielectric.

The reconfigurable antenna 600 may include an antenna dielectric 602, a magnetic bias structure 604 on the antenna dielectric 602, and a cavity 606 disposed within the antenna dielectric 602. A plurality of dielectric tiles (or platelets) 608 may be disposed within the cavity 606. The antenna dielectric 602 and/or the cavity 606 may be formed from zirconia, hafnium, hafnium zirconium oxide, aluminum nitride, barium strontium titanate, strontium titanate glass or thin thermoplastic films such as polyimide, Teflon, or liquid crystal polymer. The cavity 606 may be hermetically sealed from the environment using glass or another suitable material. The magnetic bias structure 604 may be formed from any conductive metal, such as copper, tungsten, cobalt, or other such metal. The dielectric tiles 608 may include a first layer 618 and a second layer 628. The first layer 618 may include ceramic, zirconia, hafnium, or any other suitable dielectric. The second layer 628 may include a magnetic material, such as hexaferrite.

When a DC current is applied to the magnetic bias structure 604, a magnetic field may extend into the cavity 606. The plurality of dielectric tiles 608 may therefore move within the cavity 606 due to the magnetic field. The characteristics of the reconfigurable antenna 600 may therefore be altered by changing the arrangement of the dielectric tiles 608 within the cavity 606.

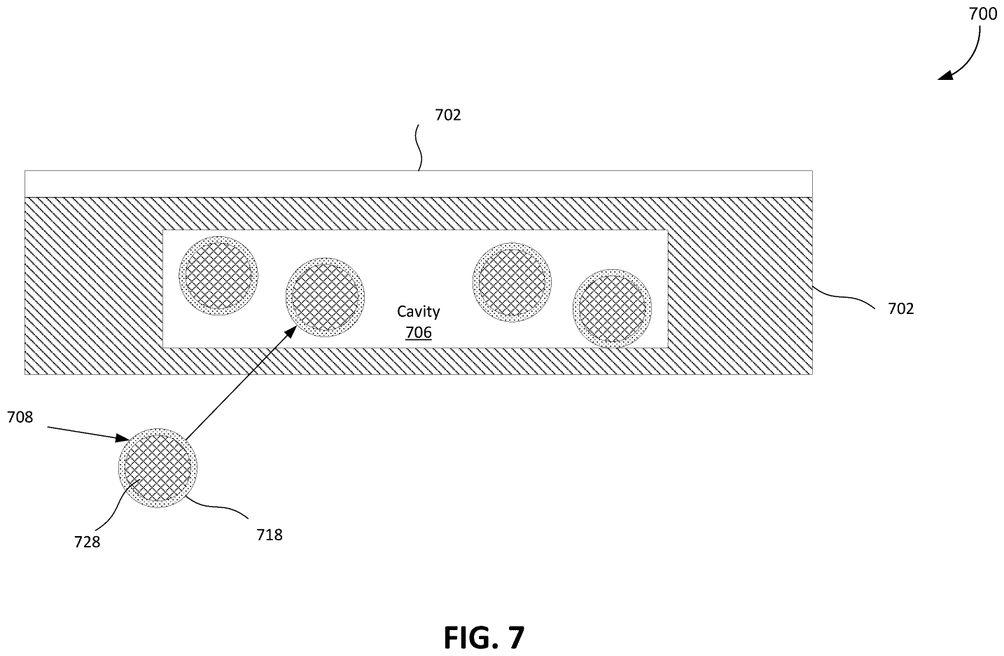

FIG. 7 illustrates a reconfigurable antenna 700 with a plurality of core/shell structures 708, according to certain embodiments. The reconfigurable antenna 700 may be included in an electronic device, such as an advanced package, or some other device. Similar to the tunable patch element 200 in FIGS. 2A-B, the reconfigurable antenna 700 may be tuned in order to reduce the effects of EMI (both as a victim and an aggressor), improve performance, change transmission/reception frequencies, or be otherwise altered.

The reconfigurable antenna 700 may be similar to the reconfigurable antenna 600 except that instead of dielectric tiles 608, a plurality of core/shell structures 708 may be disposed within the cavity 706. The core/shell structures 708 may include a shell 718 and a core 728. The shell 718 may include a ceramic, zirconia, hafnium, hafnium zirconium oxide, aluminum nitride, barium strontium titanate, strontium titanate, or any other suitable dielectric. The core 728 may include a magnetic material, such as hexaferrite. When a DC current is applied to the magnetic bias structure 704, a magnetic field may extend into the cavity 706. The plurality of core/shell structures 708 may therefore move within the cavity 706 due to the magnetic field. The characteristics of the reconfigurable antenna 700 may therefore be altered by changing the arrangement of the core/shell structures 708 within the cavity 706.

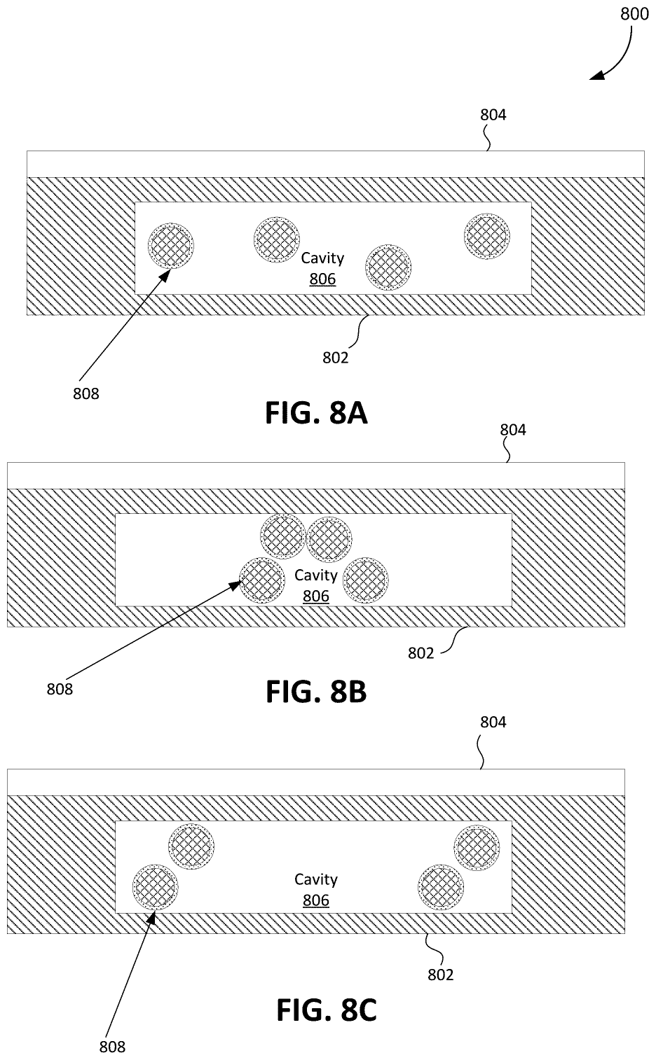

FIGS. 8A-C illustrate a reconfigurable antenna 800 with core/shell structures 808 within a cavity 806, according to certain embodiments. The reconfigurable antenna 800 may be similar to the reconfigurable antenna 700 in FIG. 7 and include similar components and functionalities. The reconfigurable antenna 800 may include an antenna dielectric 802, a magnetic bias structure 804, a cavity 806 disposed within the antenna dielectric 802, and a plurality of core/shell structures 808. Although the reconfigurable antenna 800 is shown with the core/shell structures 808, the reconfigurable antenna 800 may additionally or alternatively include dielectric tiles, such as the dielectric tiles 608 in FIG. 6.

In FIG. 8A, the reconfigurable antenna 800 may be in a first state. For example, the reconfigurable antenna 800 may not be in operation. The first state may be characterized by a first current being provided to the magnetic bias structure 804, thereby generating a first magnetic field. The first current may be provided by a controller module, such as the control module 310 in FIG. 3. In some embodiments, there may be no current provided to the magnetic bias structure, the core/shell structures 808 my be at random locations within the cavity 806.

In FIG. 8B, the reconfigurable antenna 800 may be in a second state. The second state may be characterized by the core/shell structures 808 being grouped roughly centrally within the cavity 806 of the reconfigurable antenna 800. A second electrical current may be supplied to the magnetic bias structure 804 such that a magnetic field forces the core/shell structures 808 to be grouped roughly centrally within the cavity 806. The second electrical current may be determined based on a desired performance of the reconfigurable antenna 800, based on EMI incident on the reconfigurable antenna, or some other factor. The second magnetic field may persist, and thus “hold” the core/shell structures 808 roughly centrally for the duration that the second current is provided to the magnetic bias structure.

In FIG. 8C, the reconfigurable antenna 800 may be in a third state. The third state may be characterized by the core/shell structures 808 being grouped at or near the perimeter of the cavity 806. A third electrical current may be supplied to the magnetic bias structure 804 such that a magnetic field forces the core/shell structures 808 to be grouped at or near the perimeter within the cavity 806. The third electrical current may be determined based on a desired performance of the reconfigurable antenna 800, based on EMI incident on the reconfigurable antenna, or some other factor. The third magnetic field may persist, and thus “hold” the core/shell structures 808 at or near the perimeter for the duration that the third current is provided to the magnetic bias structure.

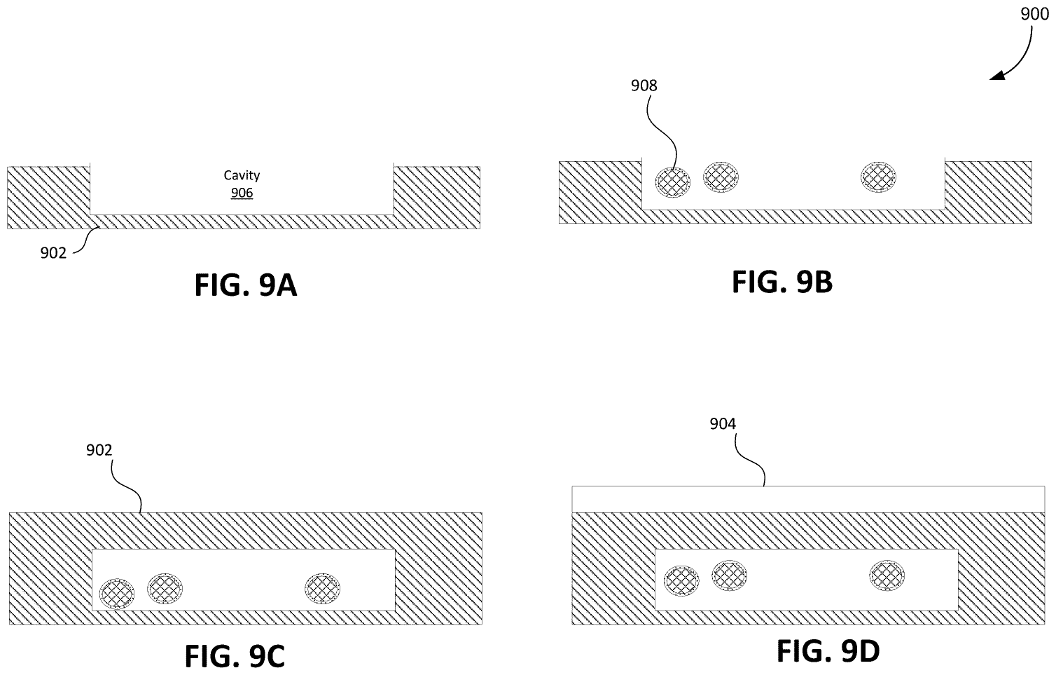

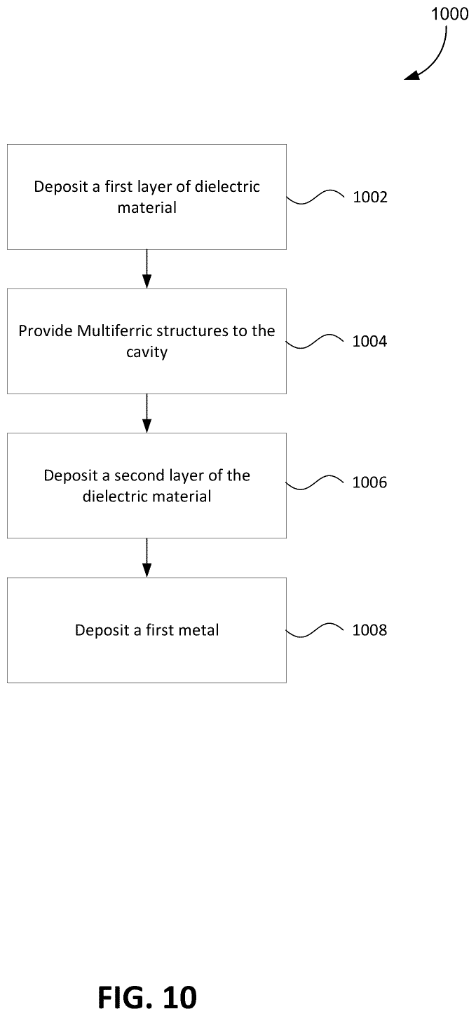

FIGS. 9A-D illustrate a manufacturing process flow for forming a reconfigurable antenna 900, according to certain embodiments. The reconfigurable antenna 900 may be similar to the reconfigurable antennas 600, 700, and/or 800 in FIGS. 6, 7, and 8, respectively. As such, the reconfigurable antenna 900 may include similar components and functionalities. The reconfigurable antenna 900 may therefore be included in an electronic device such as an advanced package or other semiconductor device. FIGS. 9A-D will be further described in relation to FIG. 10.

FIG. 10 illustrates a flowchart of a method 1000 for forming a reconfigurable antenna, according to certain embodiments. The reconfigurable antenna may be similar to the reconfigurable antenna 900 in FIGS. 9A-D. Some or all of the steps of the method 1000 may be performed in a different order than is presented here or may be combined with other steps. In some embodiments, some of the steps may be skipped altogether.

At step 1002, the method 1000 may include depositing a dielectric material 902. The dielectric material 902 may be similar to the antenna dielectric 602 in FIG. 6. The dielectric material 902 may be deposited in one or more deposition processes (e.g., CDP, VDP, etc.) such that a cavity 906 is formed within the dielectric layer 902. The cavity 906 may be open at this stage of the manufacturing process (as shown in FIG. 9A). In some embodiments, the cavity 906 may be lined with a thermoplastic film, glass, or other such material that, when sealed later in the manufacturing process, hermetically seals the cavity 906.

At step 1004, the method 1000 may include providing a plurality of multiferroic structures 908 in the cavity 906. The multiferroic structures 908 may include dielectric tiles such as the dielectric tiles 608 in FIG. 6. The dielectric tiles may be manufactured separately via a microassembly process. The cavity may be created with glass, polymer (liquid crystal polymer, paralyne-coated polymers), and/or other such materials. Hydrophobic surfaces are introduced to allow the easy movement of the dielectric tiles without stiction. The dielectric tiles may include a first layer and a second layer. The first layer may include ceramic, zirconia, hafnium, zirconium oxide, barium strontium titanate, strontium titanate, and/or any other suitable dielectric. The second layer may include a magnetic material, such as hexaferrite or other low loss magnetic oxides. Additionally or alternatively, the multiferroic structures may include core/shell structures such as the core/shell structures 708 in FIG. 7. The core/shell structures may be manufactured separately and introduced via a cavity fabrication and microassembly, and include a dielectric shell (e.g., ceramic, zirconia, hafnium, or any other suitable dielectric) and a magnetic core (e.g., hexaferrite).

At step 1006, the method 1000 may include depositing a second layer of the dielectric material 902. The second layer of the dielectric material 902 may seal the cavity 906. The cavity 906 may be at least partially sealed with the thermoplastic and/or glass prior to depositing the second layer of the dielectric material 902. Therefore, the multiferroic particles 908 may be contained within the cavity 906.

At step 1008, the method 1000 may include depositing a metal layer 904 on the second layer of the dielectric material 902. The metal layer 904 may be a magnetic bias structure similar to the magnetic bias structure 702 in FIG. 7. The metal layer 904 may include tungsten, cobalt, or other such metal. The metal layer 904 may subsequently be connected to a current source. When a current is provided to the metal layer 904, a resulting magnetic field may extend into the cavity 906, and cause the multiferroic structures 908 to be moved.

In some embodiments, shifting the permittivity from 2.2 to 1 by shifting the multiferroic particles, a change in transmission bands may be seen. The antenna transmission band may shift from 3.6 to 3. GHz by shifting the permittivity in one compartment of the antenna. If the shift is generated in two compartments, the transmission band may shift further, to 4.5 GHz. Thus, transmission and shielding may be generated in different narrow bands by tuning. This may also increase the bandwidth of the antennas as desired.

It should be understood that any of the embodiments described in relation to FIGS. 1A-1B, 2A-2B, 3, 4A-4D, 6, 7, 8A-8C, and 9A-9D may be combined, in part or in whole. For example, the tunable patch 300 may be included in the cavity 806. Thus, a patch antenna may be disposed in a cavity of a substrate. Furthermore, the tunable metamaterial resonator element 200 may be disposed atop the reconfigurable antenna 700. Other combinations of the embodiments herein would be obvious to one of ordinary skill in the art.

Each of the methods described herein may be implemented by a computer system. Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user, or may be done automatically by a computer system without human intervention where any determinations are made by a processor. Furthermore, some embodiments of each of the methods described herein may be implemented as a set of instructions stored on a tangible, non-transitory storage medium to form a tangible software product.

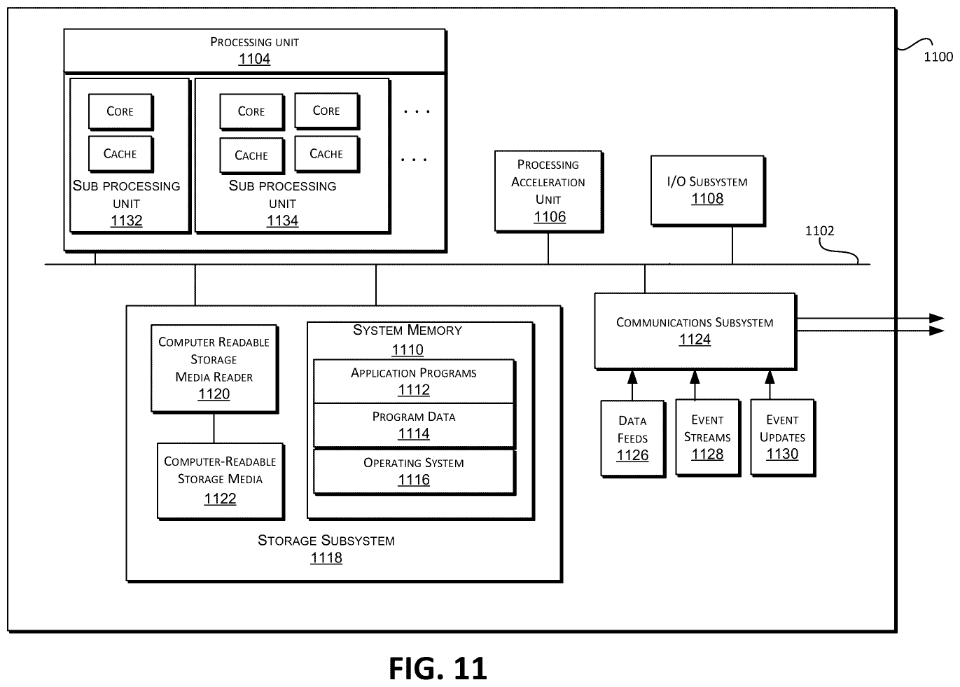

FIG. 11 illustrates an exemplary computer system 1100, in which various embodiments may be implemented. The system 1100 may be used to implement any of the computer systems described above. As shown in the figure, computer system 1100 includes a processing unit 1104 that communicates with a number of peripheral subsystems via a bus subsystem 1102. These peripheral subsystems may include a processing acceleration unit 1106, an I/O subsystem 1108, a storage subsystem 1118 and a communications subsystem 1124. Storage subsystem 1118 includes tangible computer-readable storage media 1122 and a system memory 1110.

Bus subsystem 1102 provides a mechanism for letting the various components and subsystems of computer system 1100 communicate with each other as intended. Although bus subsystem 1102 is shown schematically as a single bus, alternative embodiments of the bus subsystem may utilize multiple buses. Bus subsystem 1102 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 1104, which can be implemented as one or more integrated circuits (e.g., a conventional microprocessor or microcontroller), controls the operation of computer system 1100. One or more processors may be included in processing unit 1104. These processors may include single core or multicore processors. In certain embodiments, processing unit 1104 may be implemented as one or more independent processing units 1132 and/or 1134 with single or multicore processors included in each processing unit. In other embodiments, processing unit 1104 may also be implemented as a quad-core processing unit formed by integrating two dual-core processors into a single chip.

In various embodiments, processing unit 1104 can execute a variety of programs in response to program code and can maintain multiple concurrently executing programs or processes. At any given time, some or all of the program code to be executed can be resident in processor(s) 1104 and/or in storage subsystem 1118. Through suitable programming, processor(s) 1104 can provide various functionalities described above. Computer system 1100 may additionally include a processing acceleration unit 1106, which can include a digital signal processor (DSP), a special-purpose processor, and/or the like.

I/O subsystem 1108 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. User interface input devices may include, for example, motion sensing and/or gesture recognition devices that enables users to control and interact with an input device through a natural user interface using gestures and spoken commands. Additionally, user interface input devices may include voice recognition sensing devices that enable users to interact with voice recognition systems through voice commands.

User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader, 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments and the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 1100 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 1100 may comprise a storage subsystem 1118 that comprises software elements, shown as being currently located within a system memory 1110. System memory 1110 may store program instructions that are loadable and executable on processing unit 1104, as well as data generated during the execution of these programs.

Depending on the configuration and type of computer system 1100, system memory 1110 may be volatile (such as random access memory (RAM)) and/or non-volatile (such as read-only memory (ROM), flash memory, etc.). The RAM typically contains data and/or program modules that are immediately accessible to and/or presently being operated and executed by processing unit 1104. In some implementations, system memory 1110 may include multiple different types of memory, such as static random access memory (SRAM) or dynamic random access memory (DRAM). In some implementations, a basic input/output system (BIOS), containing the basic routines that help to transfer information between elements within computer system 1100, such as during start-up, may typically be stored in the ROM. By way of example, and not limitation, system memory 1110 also illustrates application programs 1112, which may include client applications, Web browsers, mid-tier applications, relational database management systems (RDBMS), etc., program data 1114, and an operating system 1116.

Storage subsystem 1118 may also provide a tangible computer-readable storage medium for storing the basic programming and data constructs that provide the functionality of some embodiments. Software (programs, code modules, instructions) that when executed by a processor provide the functionality described above may be stored in storage subsystem 1118. These software modules or instructions may be executed by processing unit 1104. Storage subsystem 1118 may also provide a repository for storing data used in accordance with some embodiments.

Storage subsystem 1100 may also include a computer-readable storage media reader 1120 that can further be connected to computer-readable storage media 1122. Together and, optionally, in combination with system memory 1110, computer-readable storage media 1122 may comprehensively represent remote, local, fixed, and/or removable storage devices plus storage media for temporarily and/or more permanently containing, storing, transmitting, and retrieving computer-readable information.

Computer-readable storage media 1122 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 1100.

By way of example, computer-readable storage media 1122 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD or other optical media. Computer-readable storage media 1122 may include, but is not limited to, flash memory cards, universal serial bus (USB) flash drives, secure digital (SD) cards, DVD disks, digital video tape, and the like. Computer-readable storage media 1122 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 1100.

Communications subsystem 1124 provides an interface to other computer systems and networks. Communications subsystem 1124 serves as an interface for receiving data from and transmitting data to other systems from computer system 1100. For example, communications subsystem 1124 may enable computer system 1100 to connect to one or more devices via the Internet. In some embodiments communications subsystem 1124 can include radio frequency (RF) transceiver components for accessing wireless voice and/or data networks (e.g., using cellular telephone technology, advanced data network technology, such as 3G, 4G, 5G, or EDGE (enhanced data rates for global evolution), WiFi (IEEE 802.11 family standards, or other mobile communication technologies, or any combination thereof), global positioning system (GPS) receiver components, and/or other components. In some embodiments communications subsystem 1124 can provide wired network connectivity (e.g., Ethernet) in addition to or instead of a wireless interface.

In some embodiments, communications subsystem 1124 may also receive input communication in the form of structured and/or unstructured data feeds 1126, event streams 1128, event updates 1130, and the like on behalf of one or more users who may use computer system 1100.

By way of example, communications subsystem 1124 may be configured to receive data feeds 1126 in real-time from users of social networks and/or other communication services, web feeds such as Rich Site Summary (RSS) feeds, and/or real-time updates from one or more third party information sources.

Additionally, communications subsystem 1124 may also be configured to receive data in the form of continuous data streams, which may include event streams 1128 of real-time events and/or event updates 1130, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 1124 may also be configured to output the structured and/or unstructured data feeds 1126, event streams 1128, event updates 1130, and the like to one or more databases that may be in communication with one or more streaming data source computers coupled to computer system 1100.

Due to the ever-changing nature of computers and networks, the description of computer system 1100 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

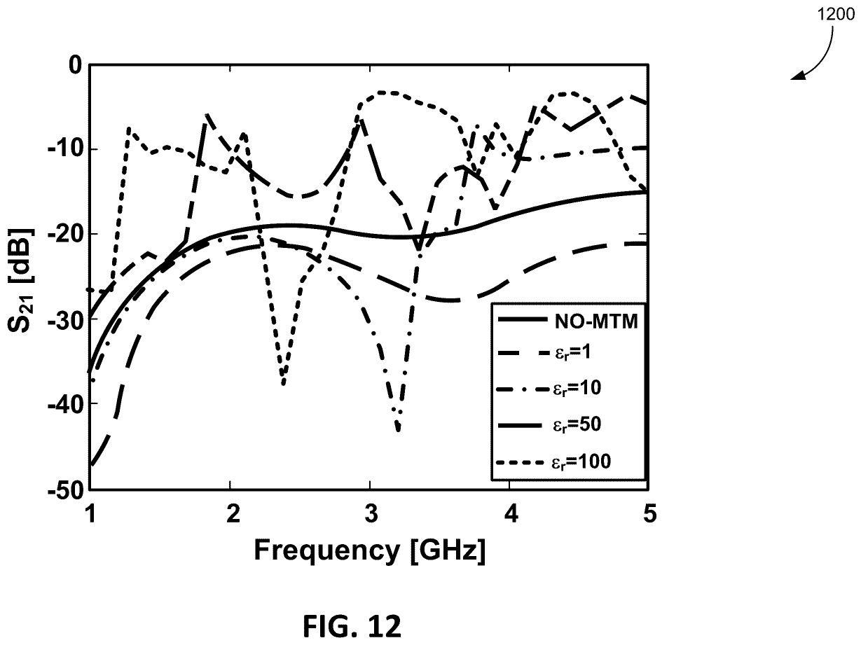

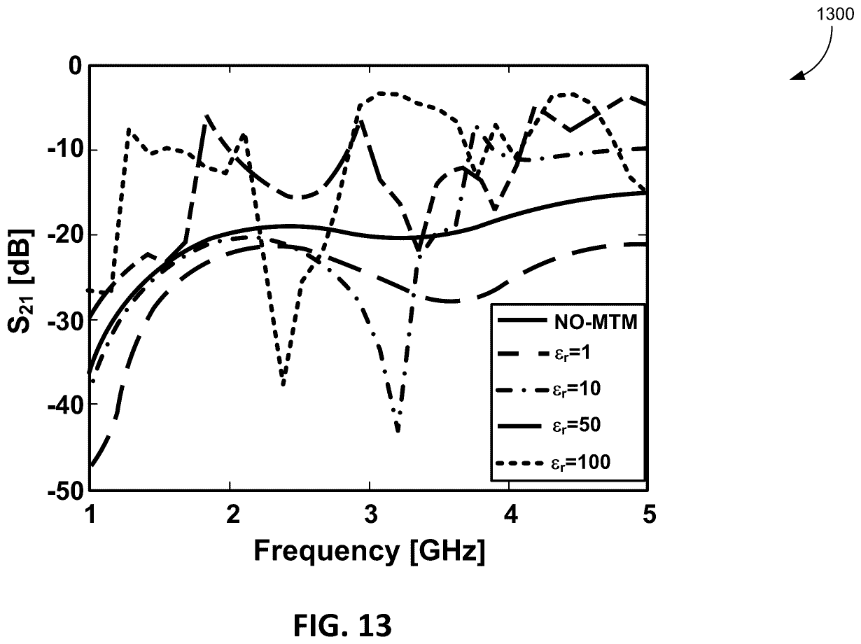

FIG. 12 illustrates a graph 1200 of isolation vs. frequency response due to a change in permittivity of a dielectric medium, according to certain embodiments. The graph 1200 illustrates the response with permittivity constants of the dielectric medium ranging from about 3 ε to about 7 ε. FIG. 13 illustrates a graph 1300 isolation vs. frequency response due to a change in permittivity of a dielectric medium, according to certain embodiments. The graph 1300 illustrates the response with permittivity constants of the dielectric medium ranging from about 1 ε to about 100 ε. The graphs 1200 and 1300 may represent a change in permittivity by moving multiferroic structures within a dielectric (e.g., in the reconfigurable antennas described in relation to FIGS. 7, 8A-C, and 9A-D). As shown in the graphs 1200 and 1300, changing the permittivity by moving the multiferroic structures inside the dielectric medium may result in a change in the transmission bands between two adjacent transmission lines that are coupled to each other. This change may be seen in some of the embodiments herein through the analysis of the S21 spectral bands for quantifying the cross-talk between the two coupled lines. For example, extra isolation of 20 dB in an operation frequency of 3-4 GHz may be achieved through this dielectric shift from 3 ε to 7 ε using oxide dielectrics coupled with hexaferrites. Increasing the permittivity to about 10 ε to about 70 ε with multicomponent oxides such as barium strontium titanate/hafnium zirconium oxide, hexaferrites, and/or or other magnetic materials may change the function of the patch structure from blocking the electromagnetic waves to transmitting them. With higher permittivity in multiferroics, this effect may be increased. For example, when εᵣ equals 100, the operation frequency may shift to 2.4 GHz instead of 3.2 GHz at εᵣ of 5.4. On the other hand, at εᵣ=50, the transmission characteristics may be improved by 5 dB towards the transmitted signal.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMS, EEPROMs, magnetic or optical cards, flash memory, or other types of machine-readable mediums suitable for storing electronic instructions. Alternatively, the methods may be performed by a combination of hardware and software.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

What is claimed is:

1. A tunable shielding system, comprising:
a substrate;
a dielectric layer disposed on a surface of the substrate;
a tunable metal patch comprising a metal plate attached to the substrate and encompassed in a magnetic layer, the tunable metal patch configured to be geometrically shifted;
a direct current coil adjacent to the metal plate;
a current source;
one or more processors; and
a non-transitory computer readable medium comprising instruction that, when executed by the one or more processors, cause the system to perform operations to:
determine, by the system, that an electromagnetic interference signal is incident on the system, the electromagnetic interference signal characterized by a frequency;
determine, by the system, a current amount associated with the frequency; and
provide, by the current source of the system, the current amount to the direct current coil such that a magnetic field is generated that causes the tunable metal patch to geometrically shift.

2. The tunable shielding system of claim 1, wherein the dielectric layer and the tunable metal patch comprise at least one of an antenna and a metamaterial resonator ring.

3. The tunable shielding system of claim 1, wherein the tunable shielding system is integrated in a semiconductor device and the electromagnetic interference signal is generated from a source within the semiconductor device.

4. The tunable shielding system of claim 1, wherein the tunable metal patch is configured to actuate in at least one of a vertical direction and a horizontal direction in response to the magnetic field.

5. The tunable shielding system of claim 1, wherein the current amount is determined to shield the system from the electromagnetic interference signal.

6. The tunable shielding system of claim 1, wherein the magnetic layer comprises a nickel iron alloy.

7. The tunable shielding system of claim 1, wherein the metal plate is bonded to the substrate using at least one of an adhesive, solder, and a nickel-containing material.

8. The tunable shielding system of claim 1, wherein the direct current coils are integrated in the tunable shielding system.

9. The tunable shielding system of claim 1, wherein the tunable metal patch is configured as a spring and comprises one or more cuts along opposite surfaces of the tunable metal patch.

10. The tunable shielding system of claim 9, wherein the spring is formed from at least one of a metal and a polymer.

11. A method comprising:
forming a tunable metal patch by:
depositing a first metal layer;
depositing a second metal layer on the first metal layer;
depositing a third metal layer;
depositing a bonding layer on the second metal layer;
patterning the tunable metal patch such that the tunable metal patch is able to actuate in at least one direction in response to a magnetic field; and
providing a metal coil about the tunable metal patch, the metal coil configured to provide the magnetic field to the tunable metal patch.

12. The method of claim 11, wherein the first metal layer comprises nickel ferrite.

13. The method of claim 11, wherein the second metal layer comprises a copper containing material.

14. The method of claim 11, wherein the bonding layer comprises a nickel containing material.

15. The method of claim 11, wherein the tunable metal patch is attached to substrate comprising at least one of zirconia, hafnium, aluminum, tungsten, and cobalt.

16. The method of claim 11, further comprising:
determining that an electromagnetic interference signal is incident on a system 2 comprising the tunable metal patch, the electromagnetic interference signal characterized by a frequency;
determining a current amount associated with the frequency; and
providing the current amount to the metal coil such that a magnetic field is generated that causes the tunable metal patch to geometrically shift.

17. A patch antenna, comprising:
an antenna dielectric;
a cavity disposed in the antenna dielectric;
a plurality of multiferroic structures within the cavity disposed in the antenna dielectric;
a magnetic bias structure, configured to provide a magnetic field within the cavity of the antenna dielectric; and
a controller configured to provide a current to magnetic actuator structure such that the plurality of multiferroic structures alter their position within the cavity.

18. The patch antenna of claim 17, wherein the multiferroic structures are platelets comprising at least one of aluminum, zirconia, and hexaferrite.

19. The patch antenna of claim 17, wherein the multiferroic structures are beads comprising at least one of aluminum, zirconia, hafnium zirconium oxide, barium strontium titanate, strontium titanate, and hexaferrite.

20. The patch antenna of claim 17, wherein the cavity comprises at least one of glass, liquid crystal polymer, parylene-coated polymer, and Teflon.
